(19) United States
(12) Patent Application Publication
(10) Pub. No.: US 2016/0049359 A1
(43) Pub. Date: Feb. 18, 2016

(54) INTERPOSER WITH CONDUCTIVE POST AND FABRICATION METHOD THEREOF

(71) Applicant: Siliconware Precision Industries Co., Ltd., Taichung (TW)

(72) Inventors: Ching-Wen Chiang, Taichung (TW); Kuang-Hsin Chen, Taichung (TW); Hsien-Wen Chen, Taichung (TW)

(21) Appl. No.: 14/744,289

(22) Filed: Jun. 19, 2015

(30) Foreign Application Priority Data
Aug. 12, 2014 (TW) TW103127576

(51) Int. Cl. H01L 23/498; H01L 21/48

(52) U.S. Cl. CPC H01L 23/49827; H01L 23/49822; H01L 23/49838; H01L 21/4857; H01L 21/486; H01L 23/49811

(57) ABSTRACT

An interposer is provided, including a substrate body, a plurality of conductive posts formed in the substrate body, and a plurality of conductive pads formed on the substrate body and electrically connected to the conductive posts. The conductive pads and the conductive posts are integrally formed. As such, no interface is formed between the conductive pads and the conductive posts, thereby preventing delamination or cracking from occurring between the conductive pads and the conductive posts.

### BACKGROUND OF THE INVENTION

1. Field of the Invention

The present invention relates to interposers, and more particularly, to an interposer and a fabrication method thereof so as to improve the product yield.

2. Description of Related Art

Along with the rapid development of electronic industries, electronic products are developed toward the trend of multi-function and high performance. Accordingly, there have been developed various types of flip-chip packaging modules such as chip scale packages (CSPs), direct chip attached (DCA) packages and multi-chip modules (MCM), and 3D IC chip stacking technologies.

FIG. 1 is a schematic cross-sectional view of a 3D chip stack package. Referring to FIG. 1, a silicon interposer 1 is provided. The silicon interposer 1 has a chip mounting side 10b having an RDL (redistribution layer) structure 11 formed thereon, an external connection side 10a opposite to the chip mounting side 10b, and a plurality of through silicon vias (TSVs) 15′ communicating the chip mounting side 10b and the external connection side 10a. A semiconductor chip 6 having a plurality of electrode pads 60 is disposed on the chip mounting side 10b of the silicon interposer 1 and the electrode pads 90 are electrically connected to the RLD structure 11 through a plurality of solder bumps 61. The electrode pads 60 have a small pitch therebetween. Further, an underfill 62 is formed between the semiconductor chip 6 and the RDL structure 11 of the silicon interposer 1 for encapsulating the solder bumps 61. Further, a packaging substrate 7 having a plurality of bonding pads 70 is disposed on the external connection side 10b of the silicon interposer 1 and the bonding pads 70 are electrically connected to the TSVs 15′ through a plurality of conductive elements 18 such as bumps. The bonding pads 70 of the packaging substrate 7 have a large pitch therebetween. Furthermore, an encapsulant 8 is formed on the packaging substrate 7 for encapsulating the semiconductor chip 6.

FIGS. 1A to 1F are schematic cross-sectional views showing a method for fabricating the external connection side 10a of the silicon interposer 1 according to the prior art.

Referring to FIG. 1A, a substrate body 10 having a chip mounting side 10b and an external connection side 10a opposite to the chip mounting side 10b is provided and disposed on a carrier 9 via the chip mounting side 10b. An RDL structure 11 is already formed on the chip mounting side 10b of the substrate body 10.

Referring to FIG. 1B, a plurality of through holes 100 are formed in the external connection side 10a of the substrate body 10, exposing portions of the RDL structure 11.

Referring to FIG. 1C, a first insulating layer 12 is formed on the external connection side 10a and in the through holes 100 of the substrate body 10, and a conductive layer 13 is then formed on the first insulating layer 12 and in the through holes 100.

Referring to FIG. 1D, a patterning process is performed. As such, a plurality of conductive posts 15 are formed in the through holes 100 to serve as the TSVs 15′ of FIG. 1, and the conductive layer 13 on the substrate body 10 is removed. The conductive posts 15 are electrically connected to the RDL structure 11.

Referring to FIG. 1E, another patterning process is performed. That is, a conductive layer 13′ is first formed on the substrate body 10 and the conductive posts 15, and then a resist layer 14 is formed on the conductive layer 13′. The resist layer 14 has a plurality of open areas 140 corresponding in position to the conductive posts 15. Subsequently, a plurality of conductive pads 16 are formed in the open areas 140 of the resist layer 14 and electrically connected to the conductive posts 15.

Referring to FIG. 1F, the resist layer 14 and the conductive layer 13′ under the resist layer 14 are removed.

Referring to FIG. 1G a second insulating layer 19 is formed on the substrate body 10 and the conductive pads 16 and partially exposes each of the conductive pads 16. Then, a UBM (Under Bump Metallurgy) layer 17 is formed on the exposed portions of the conductive pads 16 and the second insulating layer 19.

Referring to FIG. 1H, excess portions of the UBM layer 17 are removed to form a UBM layer 17′ on each of the conductive pads 16. Then, a conductive element 18 is formed on the UBM layer 17′ on each of the conductive pads 16.

Thereafter, the carrier 9 is removed. As such, a silicon interposer 1 of FIG. 1 is obtained.

However, in the above-described fabrication method of the silicon interposer 1, since the conductive posts 15 and the conductive pads 16 are fabricated separately, two patterning processes are required (for example, two processes are required to form the conductive layers 13, 13′, respectively), thus complicating the fabrication process, increasing the fabrication cost and reducing the production efficiency.

Further, since the conductive pads 16 and the conductive posts 15 are fabricated in different processes, an interface will be formed between the conductive pads 16 and the conductive posts 15. As such, delamination or cracking easily occurs between the conductive pads 16 and the conductive posts 15.

Furthermore, another patterning process is required in forming the UBM layer 17′. That is, the UBM layer 17 is first formed on the entire surface of the structure by sputtering and then a photoresist layer (not shown) is formed and a patterning process is performed on the UBM layer 17 to form the UBM layer 17′. Since the above-described method needs to perform multiple patterning processes, the overall fabrication process is quite complicated and time-consuming Consequently, the fabrication cost is increased and the product yield is reduced.

Therefore, there is a need to provide an interposer and a fabrication method thereof so as to overcome the above-described drawbacks.

### SUMMARY OF THE INVENTION

In view of the above-described drawbacks, the present invention provides an interposer, which comprises: a substrate body having opposite first and second sides and a plurality of through holes in communication with the first side; a plurality of conductive posts formed in the through holes; and a plurality of conductive pads formed on the conductive posts and the first side of the substrate body and electrically connected to the conductive posts, wherein the conductive pads and the conductive posts are integrally formed.

The present invention further provides a method for fabricating an interposer, which comprises the steps of: providing a substrate body having opposite first and second sides; forming a plurality of through holes in the first side of the substrate body; forming a resist layer on the first side of the substrate body, wherein the resist layer has a plurality of open areas correspondingly communicating with the through holes; forming a conductive material in the through holes and the open areas so as to form in the through holes a plurality of conductive posts and form in the open areas a plurality of conductive pads electrically connected to the conductive posts, wherein the conductive pads and the conductive posts are integrally formed; and removing the resist layer.

In the above-described method, the conductive material can be formed by electroplating.

In the above-described interposer and method, the substrate body can be a semiconductor plate or an insulating plate.

In the above-described interposer and method, the first side of the substrate body can have at least a passivation layer formed thereon.

In the above-described interposer and method, each of the through holes can have an extending open portion in communication with the first side of the substrate body so as for the corresponding conductive post to be formed with an extending conductive portion, wherein the extending conductive portion is greater in projective width than the base portion of the conductive post.

In the above-described interposer and method, the substrate body can be an insulating plate and have at least an electronic element embedded therein.

In the above-described interposer and method, the second side of the substrate body can have a circuit structure formed thereon. Before formation of the resist layer, portions of the circuit structure can be exposed from the through holes. The conductive posts can be electrically connected to the circuit structure.

Before forming the resist layer, the above-described method can further comprise forming an insulating layer on the first side and in the through holes of the substrate body, allowing the resist layer to be formed on the insulating layer on the first side of the substrate body. Therefore, the above-described interposer can further comprise an insulating layer formed on the first side of the substrate body and extending between the first side and the conductive pads and between the through holes and the conductive posts.

In the above-described method, forming the conductive material can comprise: forming a conductive layer on the first side and in the through holes of the substrate body; forming the resist layer on the conductive layer on the first side of the substrate body; forming the conductive material in the through holes and the open areas; and removing the resist layer and the conductive layer under the resist layer. Therefore, the above-described interposer can further comprise a conductive layer formed between the first side of the substrate body and the conductive pads and between the through holes and the conductive posts.

In the above-described interposer and method, a plurality of conductive elements can be formed on the conductive pads. For example, the conductive elements can be formed on the conductive pads before formation of the resist layer.

In the above-described interposer and method, an electronic device can be mounted on the conductive pads.

According to the present invention, only one patterning process is required to form the conductive posts and the conductive pads, thus simplifying the fabrication process, reducing the fabrication cost and improving the product yield.

Further, since the conductive pads and the conductive posts are integrally formed, no interface is formed between the conductive pads and the conductive posts. Therefore, the present invention prevents delamination or cracking from occurring between the conductive pads and the conductive posts.

### BRIEF DESCRIPTION OF DRAWINGS

FIG. 1 is a schematic cross-sectional view of a conventional interposer;

FIGS. 1A to 1H are schematic cross-sectional views showing a method for fabricating an interposer according to the prior art;

FIGS. 2A to 2G are schematic cross-sectional views showing a method for fabricating an interposer according to a first embodiment of the present invention;

FIG. 2H is a schematic cross-sectional view showing a process performed after the process of FIG. 2G;

FIGS. 3A to 3F are schematic cross-sectional views showing a method for fabricating an interposer according to a second embodiment of the present invention; and

FIG. 4 is a schematic cross-sectional view showing a method for fabricating an interposer according to a third embodiment of the present invention.

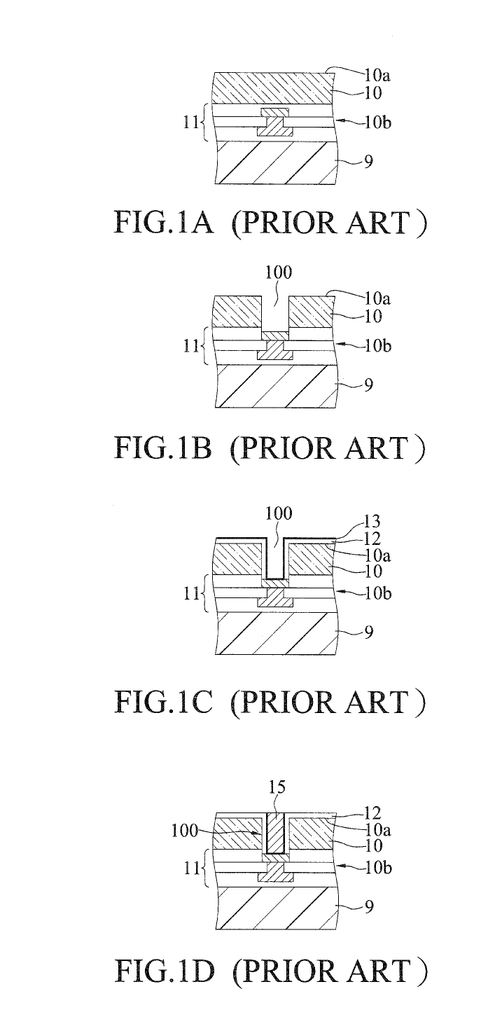

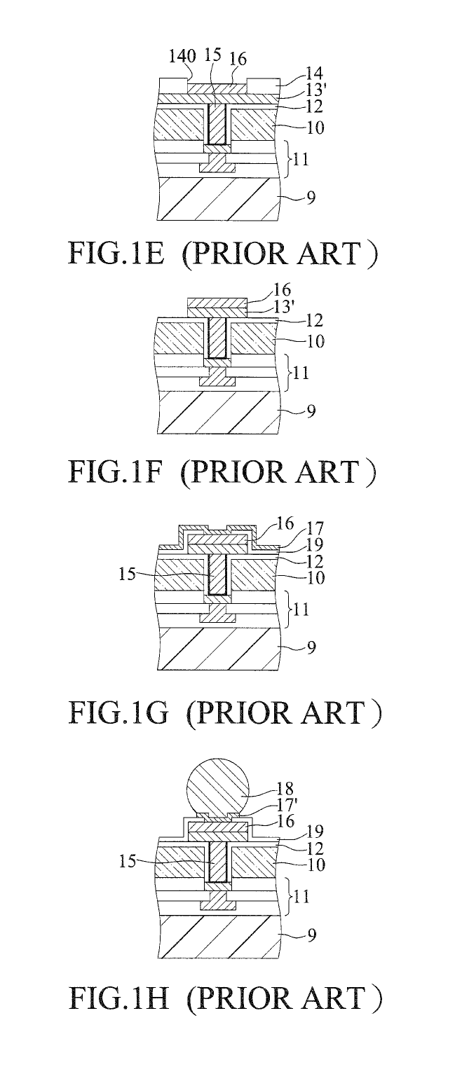

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “on”, “a” etc. are merely for illustrative purposes and should not be construed to limit the scope of the present invention.

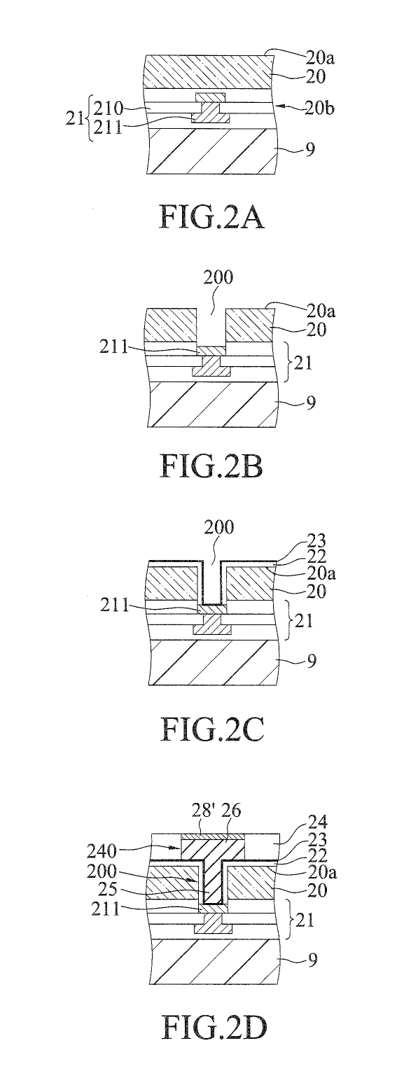

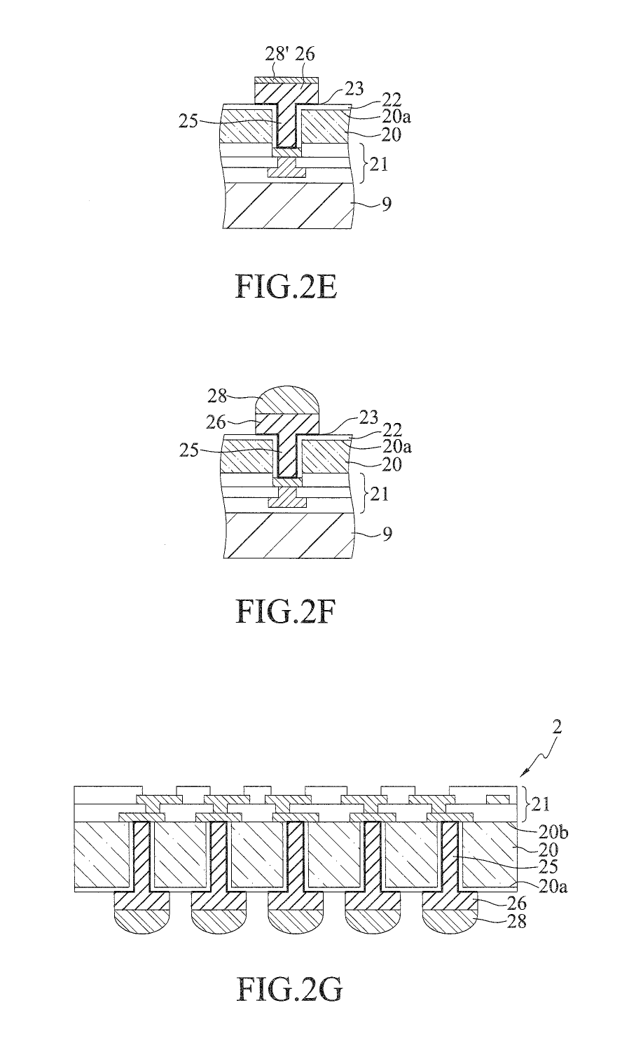

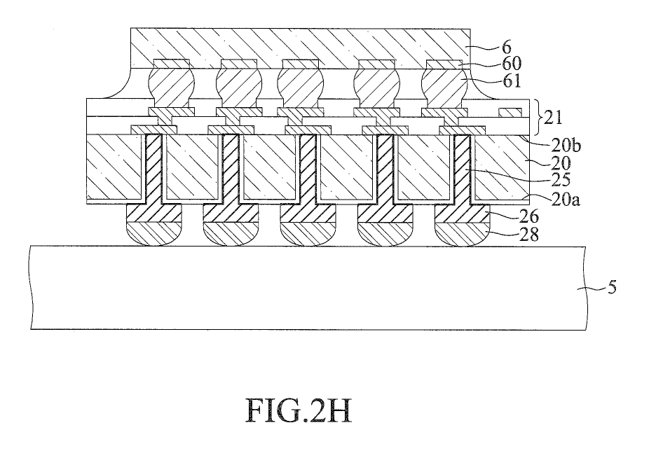

FIGS. 2A to 2G are schematic cross-sectional views showing a method for fabricating an interposer 2 according to a first embodiment of the present invention.

Referring to FIG. 2A, a substrate body 20 having a first side 20a (i.e., an external connection side) and a second side 20b (i.e., a chip mounting side) opposite to the first side 20a is provided. The substrate body 20 is a semiconductor plate. The substrate body 20 is disposed on a carrier 9 via the second side 20b thereof.

In the present embodiment, the substrate body 20 is a silicon-containing plate, for example, a silicon wafer or a glass substrate. Through an RDL process, a circuit structure 21 is already formed on the second side 20b of the substrate body 20. The circuit structure 21 has at least a dielectric layer 210 and a circuit layer 211 formed on the dielectric layer 210.

Referring to FIG. 2B, a plurality of through holes 200 are formed in the first side 20a of the substrate body 20 and communicating with the second side 20b of the substrate body 20.

In the present embodiment, the through holes 200 expose portions of the circuit layer 211 of the circuit structure 21.

Referring to FIG. 2C, an insulating layer 22 is formed on the first side 20a and in the through holes 200 of the substrate body 20, and then a conductive layer 23 is formed on the first side 20a of the substrate body 20 and in the through holes 200.

In the present embodiment, the insulating layer 22 is an oxide layer, for example, a silicon dioxide layer, or a silicon nitride layer. Since the substrate body 20 is a semiconductor plate and has an electrical characteristic close to that of the conductive posts 25 to be formed later, the insulating layer 22 is formed to electrically insulating the substrate body 20 from the conductive posts 25 so as to avoid leakage.

Referring to FIG. 2D, a resist layer 24 is formed on the conductive layer 23 on the first side 20a of the substrate body 20. The resist layer 24 has a plurality of open areas 240 correspondingly communicating with the through holes 200.

Then, an RDL process is performed. In particular, by performing an electroplating process that uses the conductive layer 23 as a current conductive path, a conductive material is formed in the through holes 200 and the open areas 240. As such, a plurality of conductive posts 25 are formed in the through holes 200, and a plurality of conductive pads 26 are formed in the open areas 240 of the resist layer 24 and electrically connected to the conductive posts 25.

In the present embodiment, the conductive pads 26 and the conductive posts 25 are integrally formed, and the conductive posts 25 are electrically connected to the circuit layer 211 of the circuit structure 21.

Further, a solder layer 28′ is formed on each of the conductive pads 26.

Referring to FIG. 2E, the resist layer 24 and the conductive layer 23 under the resist layer 24 are removed.

Referring to FIG. 2F, the solder layer 28′ on each of the conductive pads 26 is reflowed to form a conductive element 28.

Referring to FIG. 2G, the carrier 9 is removed. As such, an interposer 2 is obtained.

Subsequently, referring to FIG. 2H, the interposer 2 is mounted on an electronic device 5, for example, a circuit board or an interposer, through the conductive elements 28. A semiconductor chip 6 having a plurality of electrode pads 60 is disposed on the interposer 2 and the electrode pads 60a of the semiconductor chip 6 are electrically connected to the outermost circuit layer 211 of the circuit structure 21 through a plurality of solder bumps 61.

In the above-described method, since the conductive material is formed through the conductive layer 23, only one patterning process is required to form the conductive posts 25 and the conductive pads 26, thus simplifying the fabrication process, reducing the fabrication cost and improving the product yield.

Further, since the conductive pads 26 and the conductive posts 25 are integrally formed, no interface is formed between the conductive pads 26 and the conductive posts 25. Therefore, the present invention prevents delamination or cracking from occurring between the conductive pads 26 and the conductive posts 25.

Furthermore, the solder layer 28′ can be formed on each of the conductive pads 26 through the conductive layer 23 by electroplating, thereby reducing the number of patterning times.

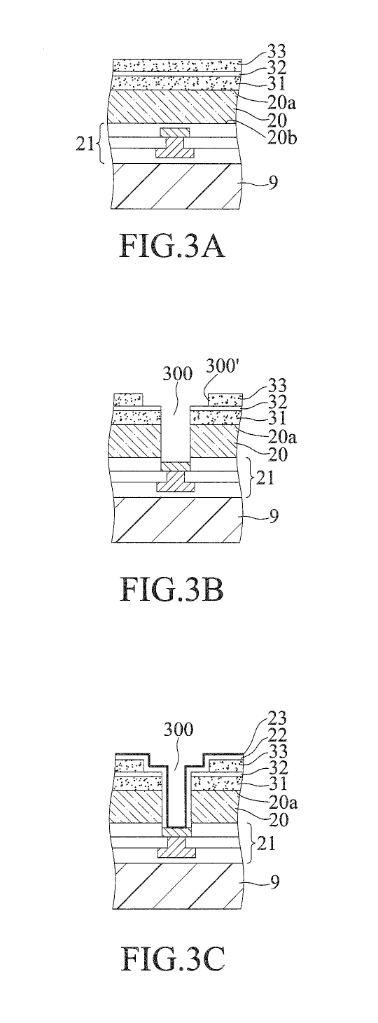

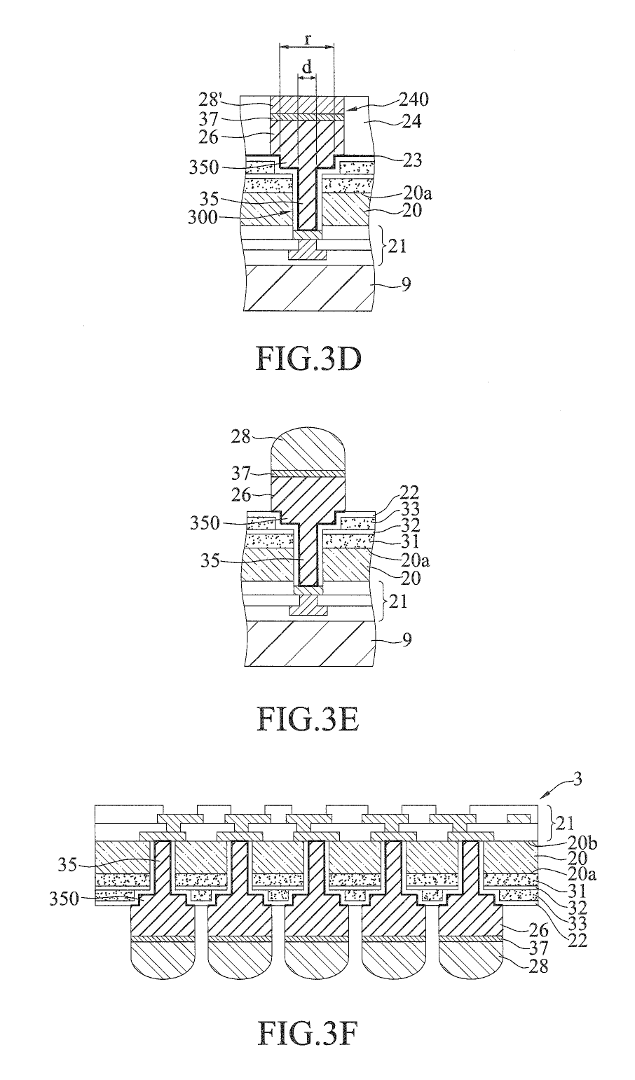

FIGS. 3A to 3F are schematic cross-sectional views showing a method for fabricating an interposer 3 according to a second embodiment of the present invention. The present embodiment differs from the first embodiment in the configuration of the substrate body and the through holes.

Referring to FIG. 3A, the first side 20a of the substrate body 20 has a first passivation layer 31, a second passivation layer 32 and a third passivation layer 33 formed thereon, and the second side of the substrate body 20 has a circuit structure 21 formed thereon.

In the present embodiment, the first, second and third passivation layers 31, 32, 33 are made of same or different materials. For example, the first and third passivation layers 31, 33 are made of an oxide layer such as silicon dioxide, and the second passivation layer 32 is made of silicon nitride.

Referring to FIG. 3B, a plurality of through holes 300 are formed in the first side 20a of the substrate body 20 and communicating with the second side 20b.

In the present embodiment, the through holes 300 penetrate the first passivation layer 31, the second passivation layer 32, the third passivation layer 33 and the substrate body 20. Each of the through holes 300 has an extending open portion 300′ formed in the third passivation layer 33. The projective width of the extending open portion 300′ is greater than that of the base portion of the through hole 300.

Referring to FIG. 3C, an insulating layer 22 is formed on the first side 20a of the substrate body 20 and in the through holes 300, and then a conductive layer 23 is formed on the insulating layer 22 and in the through holes 300.

Referring to FIG. 3D, a resist layer 24 is formed on the conductive layer 23 on the first side 20a of the substrate body 20 and has a plurality of open areas 240 correspondingly communicating with the through holes 300.

Then, a conductive material is formed in the through holes 300 and the open areas 240 through the conductive layer 23 by electroplating. As such, a plurality of conductive posts 35 are formed in the through holes 300, and a plurality of conductive pads 26 are formed in the open areas 240 and electrically connected to the conductive posts 35. Thereafter, a surface processing layer 37 is selectively formed on each of the conductive pads 26 and a solder layer 28′ is then formed on the surface processing layer 37.

In the present embodiment, each of the conductive posts 35 has an extending conductive portion 350 formed in the extending open portion 300′. The projective width r of the extending conductive portion 350 is greater than the projective width d of the base portion of the conductive post 35. For example, the projective width d of the base portion of the conductive post 35 is in a range of 10 to 50 um and the projective width r of the extending conductive portion 350 is in a range of 50 to 100 um.

Referring to FIG. 3E, the resist layer 24 and the conductive layer 23 under the resist layer 24 are removed.

Referring to FIG. 3F, the solder layer 28′ on each of the conductive pads 26 is reflowed to form a conductive element 28, and the carrier 9 is removed.

In the present embodiment, a dual damascene process is performed to increase the joint size of the conductive posts 35. That is, each of the conductive posts 35 is formed with an extending conductive portion 350. As such, the size of the conductive pads 26 can be increased to bond with a packaging substrate having large-sized joints.

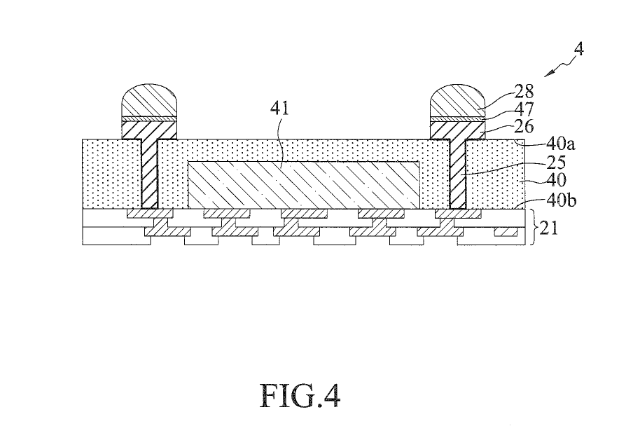

FIG. 4 is a schematic cross-sectional view showing a method for fabricating an interposer 4 according to a third embodiment of the present invention. The present embodiment differs from the first and second embodiments in the material of the substrate body.

Referring to FIG. 4, the substrate body 40 is made of an insulating material, for example, an encapsulant, and has opposite first and second sides 40a, 40b.

In the present embodiment, the interposer 4 is a fan-out wafer level package. Since the substrate body 40 is made of an insulating material, the present embodiment dispenses with the insulating layer 22.

Further, at least an electronic element 41, such as a semiconductor chip, is embedded in the second side 40b of the substrate body 40 and electrically connected to the circuit structure 21.

In addition, a UBM layer 47 is formed on each of the conductive pads 26 for bonding with the conductive element 28. The UBM layer 47 is formed on each of the conductive pads 26 through the conductive layer 23 by electroplating. As such, the present embodiment eliminates the need to form a UBM layer on the entire surface of the structure by sputtering as in the prior art, thereby reducing the number of patterning times and hence simplifying the fabrication process and reducing the material cost.

The present invention further provides an interposer 2, 3, 4, which has: a substrate body 20, 40 having a first side 20a, 40a, a second side 20b, 40b opposite to the first side 20a, 40a, and a plurality of through holes 200, 300 in communication with the first side 20a, 40a; a plurality of conductive posts 25, 35 formed in the through holes 200, 300; and a plurality of conductive pads 26 formed on the conductive posts 25, 35 and the first side 20a, 40a of the substrate body 20, 40 and electrically connected to the conductive posts 25, 35. The conductive pads 26 and the conductive posts 25, 35 are integrally formed.

In an embodiment, a circuit structure 21 is formed on the second side 20b, 40b of the substrate body 20, 40, and the conductive posts 25, 35 are electrically connected to the circuit structure 21.

In an embodiment, the interposer 2, 3, 4 further has a conductive layer 23 formed between the first side 20a, 40a of the substrate body 20, 40 and the conductive pads 26 and between the through holes 200, 300 and the conductive posts 25, 35.

In an embodiment, the interposer 2, 3, 4 further has a plurality of conductive elements 28 formed on the conductive pads 26.

In an embodiment, the substrate body 20 is a semiconductor plate.

In an embodiment, at least a passivation layer (for example, first to third passivation layers 31, 32, 33) is formed on the first side 20a of the substrate body 20.

In an embodiment, each of the through holes 300 has an extending open portion 300′ in communication with the first side 20a of the substrate body 20 so as for the corresponding conductive post 35 to be formed with an extending conductive portion 350. The projective width r of the extending conductive portion 350 is greater than the projective width d of the base portion of the conductive post 35.

In an embodiment, the substrate body 40 is an insulating plate and at least an electronic element 41 is embedded in the substrate body 40.

In an embodiment, the interposer 2, 3 further has an insulating layer 22 formed on the first side 20a of the substrate body 20 and extending between the first side 20a of the substrate body 20 and the conductive pads 26 and between the through holes 200, 300 and the conductive posts 25, 35.

In an embodiment, the interposer 2, 3, 4 further has an electronic device 4 mounted on the conductive pads 26.

According to the present invention, the conductive posts and the conductive pads are integrally formed so as to reduce the fabrication cost and prevent delamination or cracking from occurring between the conductive posts and the conductive pads.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

1. An interposer, comprising:
a substrate body having opposite first and second sides and a plurality of through holes in communication with the first side;
a plurality of conductive posts formed in the through holes; and
a plurality of conductive pads formed on the conductive posts and the first side of the substrate body and electrically connected to the conductive posts, wherein the conductive pads are integrally formed with only one end of each of the conductive posts, respectively.

2. The interposer of claim 1, wherein the substrate body is a semiconductor plate or an insulating plate.

3. The interposer of claim 1, wherein at least a passivation layer is formed on the first side of the substrate body.

4. The interposer of claim 1, wherein each of the through holes has an extending open portion in communication with the first side of the substrate body so as for the corresponding conductive post to be formed with an extending conductive portion, wherein the extending conductive portion is greater in projective width than the base portion of the conductive post.

5. The interposer of claim 1, wherein the substrate body is an insulating plate and at least an electronic element is embedded in the substrate body.

6. The interposer of claim 1, wherein a circuit structure is formed on the second side of the substrate body.

7. The interposer of claim 6, wherein the conductive posts are electrically connected to the circuit structure.

8. The interposer of claim 1, further comprising an insulating layer formed on the first side of the substrate body and extending between the first side and the conductive pads and between the through holes and the conductive posts.

9. The interposer of claim 1, further comprising a conductive layer formed between the first side of the substrate body and the conductive pads and between the through holes and the conductive posts.

10. The interposer of claim 1, further comprising a plurality of conductive elements formed on the conductive pads.

11. The interposer of claim 1, further comprising an electronic device mounted on the conductive pads.

12. A method for fabricating an interposer, comprising the steps of:
providing a substrate body having opposite first and second sides;
forming a plurality of through holes in the first side of the substrate body;
forming a resist layer on the first side of the substrate body, wherein the resist layer has a plurality of open areas correspondingly communicating with the through holes;
after forming the resist layer, forming a conductive material in the through holes and the open areas so as to form in the through holes a plurality of conductive posts and form in the open areas a plurality of conductive pads electrically connected to the conductive posts, wherein the conductive pads are integrally formed with only one end of each of the conductive posts, respectively; and
after forming the conductive material, removing the resist layer.

13. The method of claim 12, wherein the substrate body is a semiconductor plate or an insulating plate.

14. The method of claim 12, wherein the first side of the substrate body has at least a passivation layer formed thereon.

15. The method of claim 12, wherein each of the through holes has an extending open portion in communication with the first side of the substrate body so as for the corresponding conductive post to be formed with an extending conductive portion, wherein the extending conductive portion is greater in projective width than the base portion of the conductive post.

16. The method of claim 12, wherein the substrate body is an insulating plate and has at least an electronic element embedded therein.

17. The method of claim 12, wherein the second side of the substrate body has a circuit structure formed thereon.

18. The method of claim 17, wherein before formation of the resist layer, portions of the circuit structure are exposed from the through holes.

19. The method of claim 17, wherein the conductive posts are electrically connected to the circuit structure.

20. The method of claim 12, before forming the resist layer, further comprising forming an insulating layer on the first side and in the through holes of the substrate body, allowing the resist layer to be formed on the insulating layer on the first side of the substrate body.

21. The method of claim 12, wherein the conductive material is formed by electroplating.

22. The method of claim 12, wherein forming the conductive material comprises:
forming a conductive layer on the first side and in the through holes of the substrate body;
forming the resist layer on the conductive layer on the first side of the substrate body;
forming the conductive material in the through holes and the open areas; and
removing the resist layer and the conductive layer under the resist layer.

23. The method of claim 12, further comprising forming a plurality of conductive elements on the conductive pads.

24. The method of claim 12, before removing the resist layer, further comprising forming a plurality of conductive elements on the conductive pads.

25. The method of claim 12, after removing the resist layer, further comprising mounting an electronic device on the conductive pads.
